(19) United States
(12) Patent Application Publication
(10) Pub. No.: US 2026/0204512 A1
(43) Pub. Date: Jul. 16, 2026

(54) SYSTEM AND METHOD FOR A WORKSTATION FOR HANDLING ELECTRON MICROSCOPY SPECIMENS IN VARIABLE ENVIRONMENTS

(71) Applicant: Simple Origin Inc., Pittsburgh, PA (US)

(72) Inventors: Pushkarraj Deshmukh, Pittsburgh, PA (US); Jacob Schade, Apollo, PA (US); Nicholas Zurawsky, Pittsburgh, PA (US)

(21) Appl. No.: 19/448,241

(22) Filed: Jan. 14, 2026

Related U.S. Application Data
(60) Provisional application No. 63/745,469, filed on Jan. 15, 2025.
(60) Provisional application No. 63/767,079, filed on Mar. 5, 2025.
(60) Provisional application No. 63/840,269, filed on Jul. 8, 2025.

(51) Int. Cl. H01J 37/26; H01J 37/16; H01J 37/18; H01J 37/20

(52) U.S. Cl. CPC H01J 37/26; H01J 37/16; H01J 37/18; H01J 37/20

(57) ABSTRACT

This is a portable workstation designed for an electron microscopy (EM) specimen holder that allows for the handling of specimens in a gas or vacuum environment. The workstation comprises a mechanism for interfacing with an object in a gas or vacuum environment using a handling tool, resembling tweezers in an example. The mechanism may enable a user to manipulate the handling tool within the gas or vacuum environment with the requisite dexterity while working from a separate environment, such as across a hermetically sealed interface.

### CROSS-REFERENCE TO RELATED APPLICATIONS

This application claims the benefit of priority under 35 U.S.C. § 120 of U.S. Provisional Application Ser. No. 63/840,269 filed on Jul. 8, 2025, entitled DESIGN FOR A HERMETICALLY SEALED INTERFACE BETWEEN TWO ATMOSPHERIC ENVIRONMENTS THAT ALLOWS FOR PRECISE MANIPULATION OF A TOOL BY A USER IN ONE ENVIRONMENT ON A SUBJECT IN THE OTHER ENVIRONMENT, in which claims the benefit of priority under 35 U.S.C. § 120 of U.S. Provisional Application Ser. No. 63/767,079 filed on Mar. 5, 2025, entitled DESIGN FOR TRANSMISSION ELECTRON MICROSCOPY (TEM) SPECIMEN GRID BOX THAT ALLOWS FOR THE STORAGE AND TRANSPORTATION OF TEM SPECIMENS IN VACUUM ORGAS ENVIRONMENTS, in which claims the benefit of priority under 35 U.S.C. § 120 of U.S. Provisional Application Ser. No. 63/745,469 filed on Jan. 15, 2025, entitled WORKSTATION DESIGN AND PROCESS THAT ALLOWS FOR THE LOADING AND UNLOADING OF SAMPLES ONTO A TRANSMISSION ELECTRON MICROSCOPY SPECIMEN HOLDER IN A GAS OR VACUUM ENVIRONMENT the content of which is relied upon and incorporated herein by reference in its entirety.

### BACKGROUND

The specimens used in electron microscopy (EM) can be delicate and sensitive to ambient air conditions. A workstation for loading and unloading specimens onto a specimen holder is common in the field. Currently, for sensitive specimens, the loading and unloading process is aided by placing the workstation in a traditional glove box to allow the system to remain in a gas or vacuum environment while the specimens are transferred. This method is inefficient and can add significant cost to the process.

Currently, users use glove boxes that are not designed for loading and unloading specimens onto an EM specimen holder. These glove boxes are large, expensive, and inefficient for this process. Glove boxes are often shared resources used by multiple users in a lab, which can contaminate the EM specimens.

Furthermore, specimen handling is currently achieved by having the user manipulate the specimens through the use of a glove box, wherein the user inserts their hands into a glove to handle tweezers or other tools within the glove box. The current setup may require a large workspace for the user to work in and may make it difficult for the user to see the object being handled through the glove box setup. The glove box may often be a shared resource without dedicated equipment for the type of material handling required for EM specimen holders, and may be located far away from the electron microscope.

In sum, presently, there is no workstation designed for an EM specimen holder that allows for the loading and unloading of specimens in a gas or vacuum environment.

As can be seen, there is a need for a workstation design and process that allows for the loading and unloading of specimens onto an EM specimen holder in a gas or vacuum environment. The workstation design and loading process, embodied by the subject disclosure, allows for the loading and unloading of specimen(s) onto an EM specimen holder in a gas or vacuum environment. This system does not require a glove box for specimen loading and unloading onto an EM specimen holder.

### SUMMARY

The following summary is provided to introduce a selection of concepts in a simplified form that are further described in the detailed description below. This summary is not intended to identify key features or essential features of the claimed subject matter, nor is it intended to be used to limit the scope of the claimed subject matter.

This invention introduces a portable workstation designed for an electron microscopy (EM) specimen holder that allows for the handling of specimens in a gas or vacuum environment. The workstation comprises a mechanism for interfacing with an object in a gas or vacuum environment using a handling tool, resembling tweezers in an example. The mechanism may enable a user to manipulate the handling tool within the gas or vacuum environment with the requisite dexterity while working from a separate climate, such as across a hermetically sealed interface.

These and other features and advantages will be apparent from a reading of the following detailed description and a review of the appended drawings. It is to be understood that the foregoing summary, the following detailed description, and the appended drawings are explanatory only and are not restrictive of various aspects as claimed.

### BRIEF DESCRIPTION OF THE DRAWINGS

FIG. 1 is an example of the portable workstation in accordance with subject disclosure.

FIG. 2a-c are examples of the interior of a portable workstation's chamber housing in accordance with subject disclosure.

FIG. 3 is a cross-sectional view of the portable workstation in accordance with the subject disclosure.

FIG. 4 is an example of a grid box for the portable workstation in accordance with the subject disclosure.

FIG. 5 is a side view of a manipulator of the portable workstation in accordance with subject disclosure.

FIG. 6 is a cross-sectional view of a manipulator of the portable workstation in accordance with subject disclosure.

FIG. 7 is a cross-sectional view of the specimen manipulator tool of the portable workstation in accordance with the subject disclosure.

FIG. 8 is a process utilizing the portable workstation in accordance with the subject disclosure.

### DETAILED DESCRIPTION

The detailed description provided below in connection with the appended drawings is intended as a description of examples and is not intended to represent the only forms in which the present examples can be constructed or utilized. The description sets forth the functions of the examples and the sequences of steps for constructing and operating the examples. However, the same or equivalent functions and sequences can be accomplished by different examples.

The following description sets forth illustrative embodiments of integrated systems, devices, and methods that enable loading and unloading of specimens onto an electron microscopy (EM) specimen holder in a vacuum or controlled gas environment across a hermetically sealed interface, storage and transport of EM specimen grids, and enable precise manual manipulation of tools across a hermetically sealed interface. The embodiments may be practiced individually or in any operative combination.

The following description may reference the use of an electron microscope. “Electron microscope” may refer to any microscope in the EM field, such as transmission electron microscopes, scanning electron microscopes, scanning transmission electron microscopes, and other variations of electron microscopes used in the field.

References to “one embodiment,” “an embodiment,” “an example embodiment,” “one implementation,” “an implementation,” “one example,” “an example” and the like, indicate that the described embodiment, implementation or example can include a particular feature, structure or characteristic, but every embodiment, implementation or example cannot necessarily include the particular feature, structure or characteristic. Moreover, such phrases are not necessarily referring to the same embodiment, implementation, or example. Further, when a particular feature, structure, or characteristic is described in connection with an embodiment, implementation, or example, it is to be appreciated that such feature, structure, or characteristic can be implemented in connection with other embodiments, implementations, or examples, whether or not explicitly described.

The terminology used herein is for the purpose of describing particular examples only and is not intended to be limiting. As used herein, the singular forms “a,” “an,” and “the” may be intended to include the plural forms as well, unless the context clearly dictates otherwise. For example, “a” vent may include multiple vents, and the like.

As used herein, the term “and/or” includes any and all combinations of one or more of the associated listed items. Likewise, as used herein, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

Words such as “then,” “next,” etc. are not intended to limit the order of the steps; these words are simply used to guide the reader through the description of the methods.

The terms “comprises”, “comprising”, “including”, “having”, and “characterized by”, may be inclusive and therefore specify the presence of stated features, elements, compositions, steps, integers, operations, and/or components, but do not preclude the presence or addition of one or more other features, integers, steps, operations, elements, components, and/or groups thereof. Although these open-ended terms may be to be understood as non-restrictive terms used to describe and claim various aspects set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, described herein also specifically includes embodiments consisting of, or consisting essentially of, such recited compositions, materials, components, elements, features, integers, operations, and/or process steps. In the case of “consisting of”, the alternative embodiment excludes any additional compositions, materials, components, elements, features, integers, operations, and/or process steps, while in the case of “consisting essentially of”, any additional compositions, materials, components, elements, features, integers, operations, and/or process steps that materially affect the basic and novel characteristics may be excluded from such an embodiment, but any compositions, materials, components, elements, features, integers, operations, and/or process steps that do not materially affect the basic and novel characteristics may be included in the embodiment.

Any method steps, processes, and operations described herein may not be construed as necessarily requiring their performance in the particular order discussed or illustrated, unless specifically identified as an order of performance. It is also understood that additional or alternative steps may be employed, unless otherwise indicated.

In addition, features described with respect to certain example embodiments may be combined in or with various other example embodiments in any permutational or combinatory manner. Different aspects or elements of example embodiments, as disclosed herein, may be combined in a similar manner. The term “combination,” “combinatory,” or “combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included may be combinations that contain repeats of one or more items or terms, such as BB, AAA, AB, BBC, AAABCCCC, CBBAAA, CABABB, and so forth. The skilled artisan will understand that typically there is no limit on the number of items or terms in any combination, unless otherwise apparent from the context.

While specific aspects of the disclosure have been provided hereinabove, the disclosure may, however, be embodied in many different forms and should not be construed as necessarily being limited to only the embodiments disclosed herein. Rather, these embodiments may be provided so that this disclosure is thorough and complete, and fully conveys various concepts of this disclosure to skilled artisans.

All numerical quantities stated herein may be approximate, unless stated otherwise. Accordingly, the term “about” may be inferred when not expressly stated. The numerical quantities disclosed herein may be understood as not being strictly limited to the exact numerical values recited. Instead, unless stated otherwise, each numerical value stated herein is intended to mean both the recited value and a functionally equivalent range surrounding that value. At the very least, and not as an attempt to limit the application of the doctrine of equivalents to the scope of the claims, each numerical value should at least be construed in light of the number of reported significant digits and by applying ordinary rounding processes. Typical exemplary degrees of error may be within 20%, 10%, or 5% of a given value or range of values. Alternatively, the term “about” refers to values within an order of magnitude, potentially within 5-fold or 2-fold of a given value. Notwithstanding the approximations of numerical quantities stated herein, the numerical quantities described in specific examples of actual measured values may be reported as precisely as possible. Any numerical values, however, inherently contain certain errors, necessarily resulting from the standard deviation found in their respective testing measurements.

All numerical ranges stated herein include all sub-ranges subsumed therein. For example, a range of “1 to 10” or “1-10” is intended to include all sub-ranges between and including the recited minimum value of 1 and the recited maximum value of 10 because the disclosed numerical ranges may be continuous and include every value between the minimum and maximum values. Any maximum numerical limitation recited herein is intended to include all lower numerical limitations. Any minimum numerical limitation recited herein is intended to include all higher numerical limitations.

Features or functionality described with respect to certain example embodiments may be combined and sub-combined in and/or with various other example embodiments. Also, different aspects and/or elements of example embodiments, as disclosed herein, may be combined and sub-combined in a similar manner as well. Further, some example embodiments, whether individually and/or collectively, may be components of a larger system, wherein other procedures may take precedence over and/or otherwise modify their application. Additionally, a number of steps may be required before, after, and/or concurrently with example embodiments, as disclosed herein. Note that any and/or all methods and/or processes, at least as disclosed herein, may be at least partially performed via at least one entity or actor in any manner.

While particular aspects have been illustrated and described, it would be obvious to those skilled in the art that various other changes and modifications may be made without departing from the spirit and scope of the invention. Those skilled in the art will recognize or be able to ascertain, using no more than routine experimentation, numerous equivalents to the specific apparatuses and methods described herein, including alternatives, variants, additions, deletions, modifications, and substitutions. This application, including the appended claims, is therefore intended to cover all such changes and modifications that may be within the scope of this application.

Unless defined otherwise, all technical and scientific terms used herein have the same meanings as commonly understood by one of ordinary skill in the art.

Numerous specific details are set forth to provide a thorough understanding of one or more embodiments of the described subject matter. It is to be appreciated, however, that such embodiments can be practiced without these specific details.

The present invention relates to a compact, portable workstation designed to provide a hermetically sealable chamber, which may be configured to receive an electron microscopy (EM) specimen holder, store and present EM grid boxes, and allow manipulation of various EM tools with one or more hermetically sealed manipulator modules. The hermetically sealed chamber may comprise vacuum and gas valving to establish a selected internal environment (e.g., vacuum, inert gas, or other controlled atmospheres). An associated hermetically sealed EM grid box may be configured to store and transport multiple EM grids in a vacuum or gas environment. A manipulable interface module may enable a user to precisely actuate a handling tool (e.g., tweezers) inside the chamber, maintaining a hermetic barrier between environments while the user remains outside.

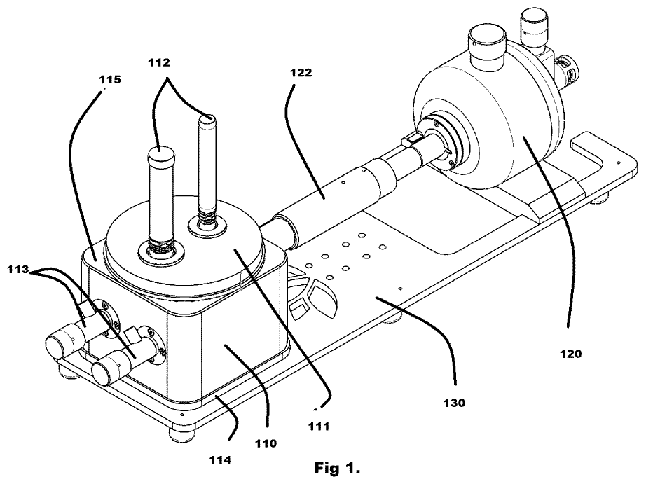

Referring to FIG. 1, the portable sealed workstation comprises a chamber housing 110 and a specimen holder 120 situated on a frame 130. The frame 130 may be steel, aluminum, composite, or other rigid material. The chamber housing 110 may be a hermetically sealable chamber housing enclosing an interior working volume. The chamber housing 110 may include sidewalls and an upper opening to receive a lid 111.

The frame may be constructed such that the chamber housing 110 is situated thereon with a bottom enclosure 114. The frame 130 may comprise an indent or cavity, such that the chamber housing 110 may be inserted therein. In various examples, the chamber housing 110 may be attached fixedly onto the frame 130.

The chamber housing 110 may be situated on one distal end of the frame 130, while a specimen holder 120 may be situated on the other distal end. The frame 130 may comprise a shelf structure that the specimen holder 120 can be placed upon. The chamber housing 110 may comprise a holder sleeve 122, wherein the specimen holder 120 may interface with the chamber housing 110 through the holder sleeve 122. When assembled, the chamber housing 110 and the specimen holder 120 may form a singular structure through the holder sleeve 122 on the platform 130.

The chamber housing 110 may comprise a bottom enclosure 114, a top enclosure 115, and a lid 111. The lid may comprise a pair of cavities, through which two manipulators 112 may be configured. The chamber housing 110 may comprise a plurality of valves 113 connected to a side enclosure of the chamber housing 110.

The portable sealed workstation may be configured to enable users to manipulate small components in a vacuum/gas environment without a glove box or other sophisticated and dedicated chambers. The portable sealed workstation may comprise a hermetic manipulator module 112, mounted to a manipulator port on the lid 111, in an example. In various implementations, the hermetic manipulator module may be configured on a wall of the housing 110.

In one embodiment, the module may include a user-actuated tool 112. The user-actuated tool 112 may be designed to resemble a pair of tweezers, in an example. The user-actuated tool 112 may be removably coupled to a tool cap via a fastener to allow rapid tool replacement or interchangeability with other instruments. The user-actuated tool 112 may be configured to adapt to microscalpels, microprobes, grippers, etc.

The chamber housing may comprise a lid 111 configured to seal the chamber housing's inner cavity. In various examples, a single lid may be configured to seat against an inner lip of the housing via an O-ring situated on the rim of the side enclosure of the chamber housing 110. In various other embodiments, an inner lid and outer lid arrangement may be used, each with respective seals (e.g., O-rings) to enhance hermeticity and serviceability. The lid 111 can include one or more manipulator ports, each with an associated hermetic interface, as well as viewports or lens mounts.

One or more vacuum and gas valves 113 may be coupled to the chamber. The vacuum valve may be configured to evacuate the interior to a desired vacuum level. The gas valve may be configured to introduce a selected gas (e.g., inert gas) to a set pressure. Both/either of the valves may be configured to vent the chamber safely to a desired atmospheric pressure setting as needed. The valves may be located on any wall or panel of the housing and may be manifolded or provided as discrete ports. Additional valves or gauges can be incorporated to suit different use cases or applications.

The portable workstation may comprise optional optical aids, such as a lens post and magnification lens. The optical aids may be aligned to provide a clear field of view of the platform area during manipulation. This further enhances the ability for a user to handle or manipulate specimens within the hermetically sealed chamber without having to physically be present within the internal volume.

The portable sealed workstation may comprise an EM holder sleeve assembly 122 mounted to the housing 110. The EM holder sleeve assembly 122 may be aligned with the platform tip seat 228. The sleeve may provide a sealed passage that accepts the barrel of an EM specimen holder 122 while allowing the holder tip 227 to be extended into or retracted from the chamber interior. Appropriate seals (e.g., O-rings, gaskets) may be utilized to maintain a hermetic barrier around the sleeve.

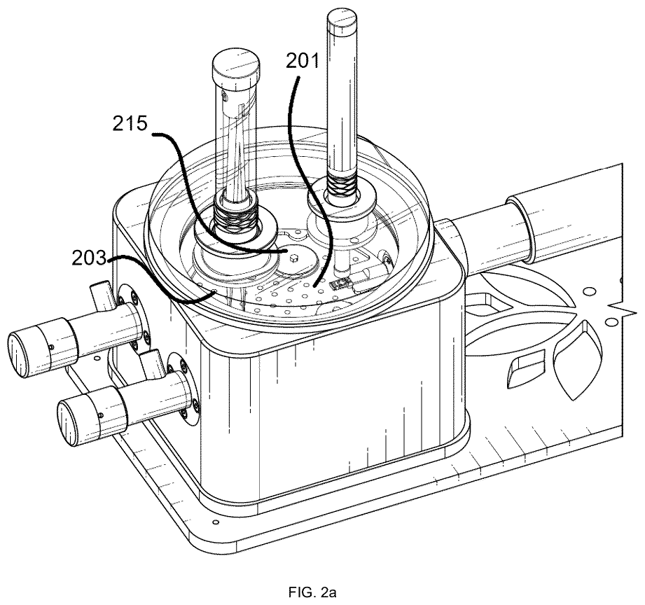

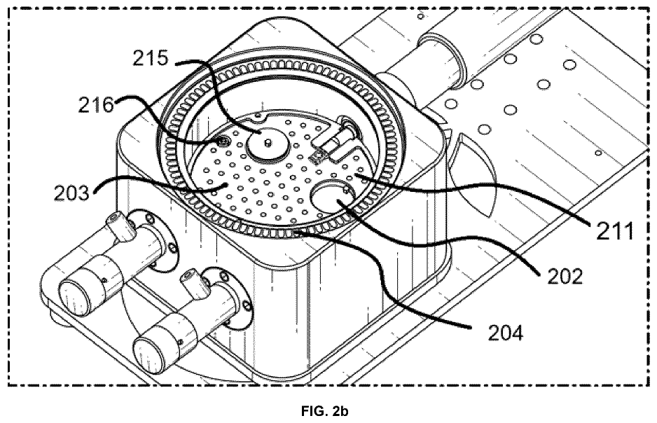

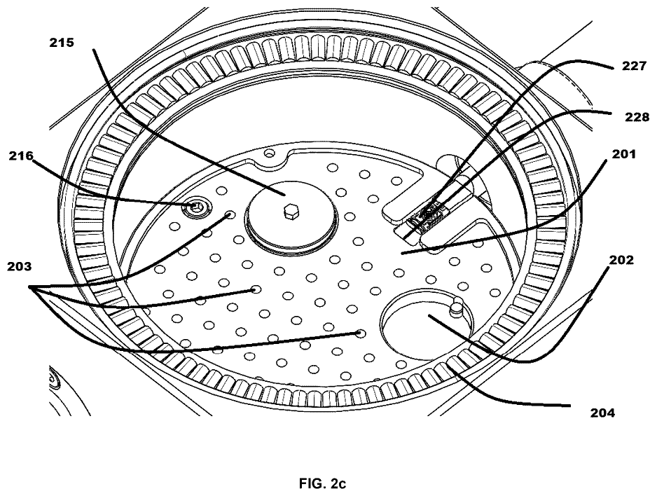

Referring to FIG. 2, an interior of the chamber housing is provided. In FIG. 2a, a version of the portable workstation is provided with the lid being shown as transparent. In practice, the lid 201 may be provided as glass, plastic, or other materials that may allow a user to see the interior of the chamber housing. This allows a user to manipulate the EM specimen within the chamber housing while providing full visibility to the interior of the chamber housing that may be under a different vacuum or pressure setting.

Referring to FIG. 2b, the chamber housing is shown without the lid and its associated components. As can be seen here, the sleeve may connect the chamber housing with the specimen holder. In various examples, the sleeve may connect with the chamber housing and form a hermetic seal, thereby allowing the tip to situate within the chamber housing while the chamber housing may be configured to be at a desired vacuum or pressure setting.

The chamber housing may comprise a chamber platform 201 as part of the lower enclosure or as an independent module secured to the base using screws 216. The platform 201 may comprise a plurality of platform apertures 203 sized for a variety of reasons, such as access, uniform gas flow, and/or weight reduction. One or more grid box docks or holders 202 may be configured to receive grid boxes, grid cassettes, or other grid carriers, hermetically sealed or not, thereon.

The grid box dock 202 may be configured to hold a grid box 215, wherein the grid box dock 202 may comprise a locking mechanism configured to secure the grid box 215. In an example, the locking mechanism may engage when the grid box 215 is inserted into the grid box holder 202, wherein the grid box would be prevented from rotating therein. In an example, a grid box 215 may comprise a lid that may be twisted off. Seating the grid box 215 into the grid box holder 202 may allow the lid to be removed without causing the grid box 215 to move.

A specimen holder tip seat 228 may be adapted to support an EM specimen holder tip 227 assembly during loading/unloading EM specimens 412. In various examples, the EM specimen 412 may be extracted from a grid box 215 by a manipulator inserted through the lid 211. This chamber housing configuration may allow transport of the EM specimen 412 when the chamber is in vacuum/gas conditions, thereby eliminating the need to process the transfer in a clean room setting.

The platform 201 of the portable workstation may be configured to accommodate different grid box formats, specimen clamping geometries, and operator preferences. The number and placement of manipulator ports, specimen holders, and valves may be customized to match workflow requirements. The workstation may be bench-top portable to allow placement near the working location, thereby minimizing transfer time and contamination risk.

The chamber housing may comprise a track 205 around its perimeter, wherein a plurality of rollers 204 may be configured along the perimeter of the chamber housing. In an example, the track 205 may sit on top of a side enclosure of the chamber housing, wherein the lid may sit on top of the bearing 205. In an example, the lid may be caused to rotate about the chamber housing along the track 204, assisted by the bearings 205 thereon. When a vacuum condition is induced within the vacuum chamber, in an example, the atmospheric pressure may exert a degree of force onto the lid and make it challenging to rotate the lid. The track 204 thereby provides relief by allowing the lid to rotate with ease when vacuum is induced in the chamber housing. Furthermore, the track 204 allows the pair of manipulators to access all areas of the chamber housing interior, as the lid may be rotated to allow the manipulators to reach a desired location.

Referring to FIG. 3, a cross-sectional view of the portable workstation is provided. The portable workstation accepts an EM specimen holder. The portable workstation may comprise a platform 302, wherein a plurality of features may be configured. The portable workstation may comprise a chamber housing situated on one end of a frame 330, wherein the EM specimen holder 120 in FIG. 1 may be situated on an opposing end of the frame 330 and have its tip, extended into the chamber housing 110 in FIG. 1. The seat 301 for the specimen holder may be situated on top of the platform 302 in an example configuration.

The portable workstation may comprise a lid 311 that is situated on top of the chamber housing on an interface feature 315 that ensures hermeticity and smooth interaction with a bearing ring 316. The bearing ring 316 may be placed on the inner lip of the chamber housing opening.

The lid may comprise a number of manipulator openings 322, wherein a plurality of manipulators 312 may be inserted. In an example, the portable workstation may comprise a pair of manipulators 312, wherein one comprises a tweezer, and one comprises a bolt driver. The bolt driver may be utilized to open and close a lid on a grid box 400, wherein the tweezers may be utilized to extract, move, and interact with any of the EM grids contained in the grid box.

The manipulators 312 may be sealed by a plurality of O-rings 321, such that the chamber housing maintains a hermetically sealed environment. Thus, the ends of the manipulators may operate within the sealed environment while the user controls the manipulators 312 in the atmospheric setting. This configuration allows users to transfer an EM specimen in a pressure/vacuum-controlled environment without needing to utilize a glove box or pressurized room.

The portable workstation may comprise at least one valve 313, which may be mounted onto the chamber housing. The valve 313 may facilitate evacuating air from within the chamber housing to create a vacuum environment therein. In various examples, the valve 313 may be utilized to introduce inert gas to cater to the specific needs of an EM specimen.

The portable workstation may comprise a plurality of hermetic seals, such as O-rings, gaskets, or equivalent sealing elements 321, at all interfaces where components meet to form a barrier to atmosphere. Such interfaces may include lid-to-housing 323, manipulator ports 322, sleeve flanges 324, valve penetrations 313, and more. The utilization of the hermetic seals may be customized to ensure hermetic integrity across multiple applications.

In an example, the specimen holder may connect with the chamber housing through the sleeve, wherein at least the O-rings at the sleeve flanges 324 may facilitate a hermetic seal at its connection. The hermetic seal may allow a vacuum/gas-infused environment, wherein the tip may extend from the sleeve into the chamber housing. This configuration allows the user to manipulate an EM specimen within a controlled vacuum/gas environment while remaining in a regular atmosphere setting.

The portable sealed workstation may comprise a vacuum-compatible manipulator module 312 through which the tools may be manipulated. The module 312 may be configured to support motion. The supported motion may comprise raising/lowering of the tool, radial articulation, and squeezing/relaxing of tweezers through compliant deformation, while maintaining a sealed barrier.

The portable sealed workstation may comprise a spring-bias system that applies a positive preload to bias the tool 312 toward a retracted or neutral position and to compensate for differential pressure forces. The spring-bias system may be implemented with a compression spring, in an example. The preload force may be customized using a washer/retainer and a spring trap or retaining ring, enabling precise tactile feedback and consistent tool positioning.

The portable sealed workstation may comprise a ball-joint assembly designed to provide multi-axis articulation. The sleeve 322 may be configured to couple to an insert seated within a spherical or gimbaled joint. The joint may be held in a bracket set, which may be configured to clamp to the lid or housing wall. The joint may be configured to support compound motions, including axial displacement and radial sweeps, thereby facilitating fine positioning of the tool tip over the working area.

The portable sealed workstation may comprise hermetic sealing elements at all interfaces. The sealing elements may comprise O-rings or gland seals between the ball joint and corresponding brackets, insert-to-sleeve junctions, and bracket-to-lid interface. In various examples, the portable sealed workstation may comprise a wave spring or other compressive elements, wherein the wave spring may be configured to apply a constant seating force to maintain seal integrity despite temperature or pressure changes.

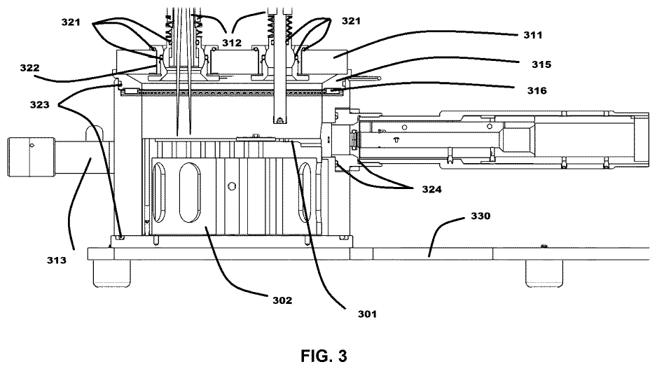

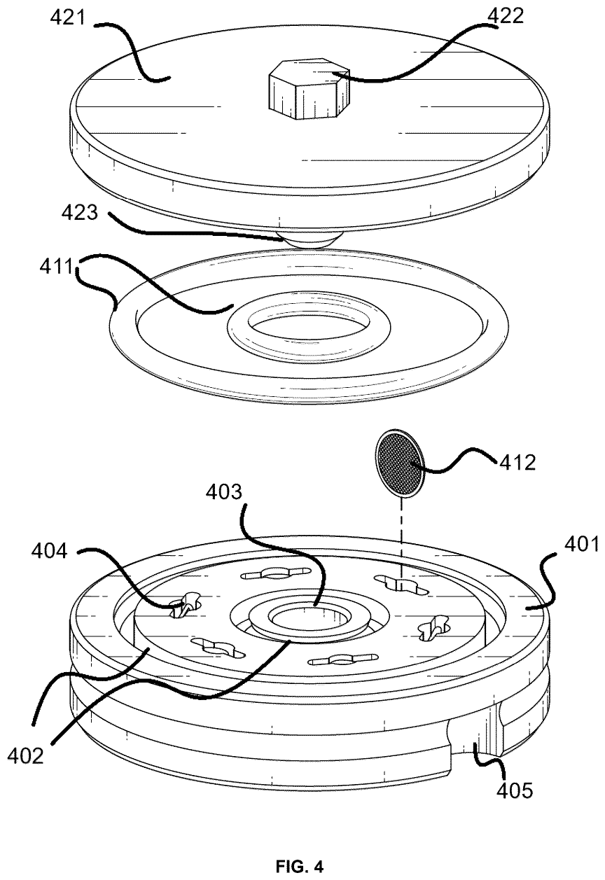

Referring to FIG. 4, the portable sealed workstation may comprise a grid box designed to hold EM specimen grids. An exploded view of the grid box is provided. The grid box comprises a circular base 401 that contains a number of slots 404 designed to store EM specimen grids 412. The outer perimeter of the top surface of the base comprises a dovetail groove 402 machined therein, wherein an O-ring 411 may be inserted. Further, a dovetail may be machined around the inner diameter 402, wherein another O-ring 411 may be inserted. In the center of the grid box base 401, a screw hole 403 may be configured therein. This screw hole 403 may be utilized to attach a lid. In an example, the grid box may be constructed of stainless steel.

The grid box base 401 may comprise an indent 405, which may be designed to interface with a locking mechanism. In an example, this key slot 405 may be designed to interact with the locking mechanism in the grid box dock 202 in FIG. 2 to prevent rotation of the grid box. The anti-rotation feature may comprise a radial slot or keyway, which may be configured to correspond with a locating pin on a dock or workstation surface to prevent base rotation during lid manipulation.

The grid box 400 may comprise dual sealing grooves in an example, formed near an outer perimeter and near an inner diameter of the base's top surface. Each groove may be designed to receive a sealing element, which may be an O-ring. When compressed by a lid, these seal elements may define a hermetically sealed volume encompassing the grid slots.

The grid box 400 may comprise a central threaded bore 403 configured to receive a lid fastener. In an example, the lid fastener may be implemented as a threaded post from the lid. The threaded interface may be designed to draw the lid down against the seals to achieve hermeticity.

In various examples, the grid box 400 may comprise a drive feature, such as an external hex 422, for engagement by a lid tool. The tool may include a complementary hex receptacle, enabling controlled tightening or removal without disturbing the base. Similar to the sealing elements and their corresponding components in the other parts of the portable sealed workstation, these sealing elements may define a hermetically sealed volume encompassing the grid slots.

The grid box 400 may comprise a sealing groove/surface that compresses sealing elements against the base when tightened, thereby isolating the interior volume.

When assembled with seals in place and the lid tightened, the interior region containing the grid slots may be hermetically sealed. The grid box may be evacuated and/or backfilled with a selected gas prior to closure or sealed under ambient conditions as desired. Alternative sealing methods include single-seal designs, gaskets, knife-edge seals, or perimeter sealing with curable materials (e.g., epoxy), provided the result is hermetic. Alternative lid fastening modes include magnetic latching, bayonet couplings, clamping rings, or press-fit designs. The grid box may be manufactured from stainless steel, aluminum, titanium, vacuum-compatible polymers (e.g., polyimides), or combinations thereof, selected to support the target vacuum/gas performance, weight, and manufacturability.

Referring to FIG. 4, a lid of the grid box is provided. The lid of the grid box 421 comprises a hexagonal protrusion 422 from the top of the lid designed to connect with a tool. The lid may also comprise a threaded protrusion 423, which may be designed to interact with the screw hole 403. When the lid 421 and grid box 401 are attached together, and the O-rings 411 are positioned in the dovetail grooves 402 to create a hermetically sealed environment inside the grid slots between the two O-rings 404.

The hermetically sealed environment is the necessary component of this design. It allows for the transport of grids in a safe environment from anywhere without the use of a vacuum storage container. The design may have any number of EM specimen grid slots. The capacity to hermetically seal the grid box may be done with the use of O-rings or another hermetic sealing method, such as gaskets or sealing the perimeter with epoxy. How the lid is fastened onto the grid box may be done in any way, such as magnetically or with a press-fit design. How the lid is removed from the grid box may be done with any configuration of tool and lid, or may not be done at all. The grid box design is made out of stainless steel to maintain a hermetically sealed environment, but may be made out of any material or combination of materials that are capable of maintaining a hermetically sealed environment, such as certain polymers like polyimides and certain metals, including aluminum and titanium.

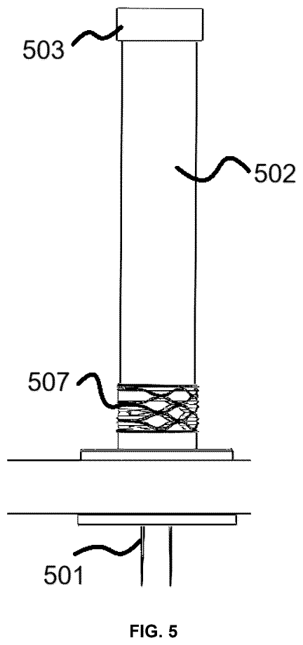

Referring to FIG. 5, a side view of the manipulator to be used in the portable workstation is provided. The manipulator in this example comprises a pair of tweezers enveloped in a sleeve 502, wherein a cap 503 may be configured on a distal end of the sleeve 502. The manipulator may be situated on a cap of the chamber enclosure, such as a cap 111 in FIG. 1. The sleeve 502 may be configured with a spring 507, wherein a certain range of motion and feedback force may be supported for the manipulator.

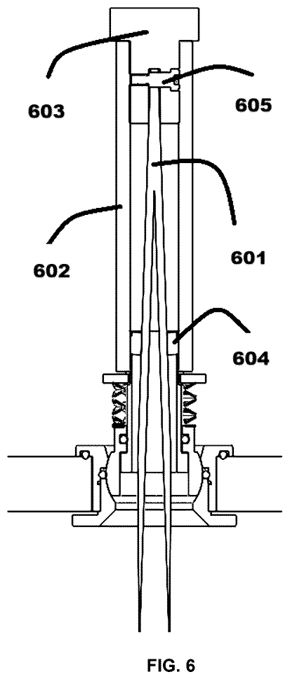

The product is a system designed to allow the user to manipulate a tool in a gas or vacuum environment while the user is in a separate environment. In the exemplary embodiment provided in FIG. 6, the manipulator tool may be a tweezer, but it may be any instrument that requires manipulation. The product allows the user to perform manipulations on the tool in a vacuum or gas environment that they would otherwise have to rely on automation or a more cumbersome setup to accomplish. The tweezers 601 are secured to a cap 603 by a removable screw 605. The cap 603 and tweezers 601 may be configured into a sleeve 602, which may enable a variety of movements for the tweezers 601. In various examples, the tweezers 601 may be moved vertically, horizontally, laterally, and rotationally.

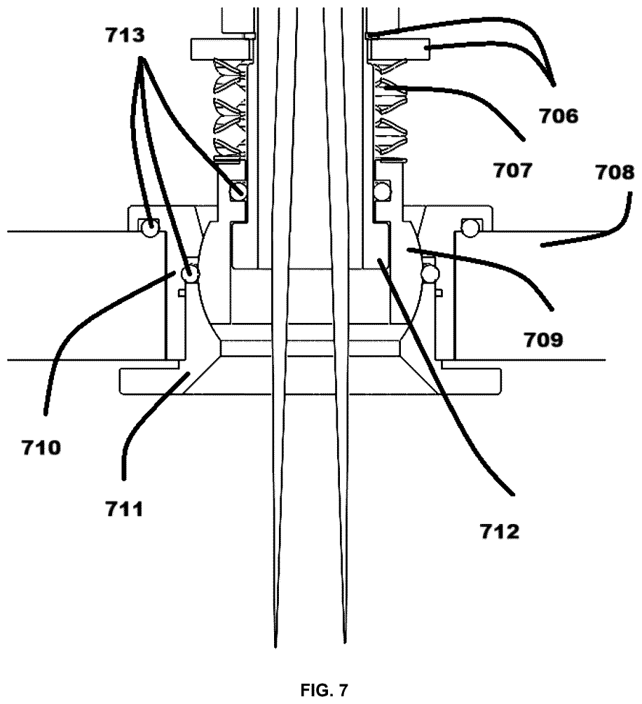

Referring to FIGS. 6-7 together, a spring 707 may provide a positive force greater than the atmospheric pressure on the sleeve 602 and cap 603, which allows the tweezers 601 to remain suspended above the system, requiring the user to apply force to push the sleeve down to compress the spring 707. In the exemplary embodiment, the sleeve 602 is flexible Tygon. The flexibility of the sleeve 602 allows the user to compress the tweezers and use them in a typical way while maintaining the integrity of the vacuum environment. Another feature of the flexible sleeve construction is its ability to enable hermetic seals at interfaces through the full range of motions by the tweezers. In this example, the tweezer sleeve 602 may be situated between the cap 603 and the ball joint housing 709, any movement in the tweezer sleeve 602 may not lead to changes to any of the seal surfaces associated with the ball joint itself.

To make compression of the tweezers 601 easier, the system includes spacers 604 mounted on the tines of the tweezers 601 at a location designed to make manipulation of the tweezers through the sleeve 602 easier. The tweezers 601 are set into a ball joint 709 on whichever surface the system is set in; in the exemplary embodiment, it is set into a glass disk 708. This ball joint 709 allows the user to move the tweezers 601 radially as well as axially.

The system is designed to be modular, allowing the user to swap out the tweezers 601 with minimal effort if they should get dull or otherwise unusable. This is facilitated by the fact that the sleeve 602 can be removed.

The ball joint 709 is secured to the surface by two support brackets 710-711. These brackets 710-711, along with the ball joint 709 itself, are hermetically sealed via the use of O-rings 713. In this design, the brackets 710-711 may ensure a hermetic seal due to their positioning in relation to each other, in addition to the O-rings 713. In an example, a wave spring may be implemented to apply a positive force on the bottom surface to ensure the top bracket 710 remains firmly fixed to the lid.

The sleeve 602 interfaces with the ball joint 709 via a specialized tube 712 inserted into the ball joint 709. This insert is designed to maintain a hermetic seal while allowing the tweezers 601 to be moved up and down. The insert 712 is also equipped with mounting for a washer and retaining ring 706, which allows the user to pre-load the spring 707 and gives the sleeve 602 a solid surface to rest on.

In various aspects, alternative implementations may be utilized to achieve specific application goals. The cap 603 may be altered in various ways to achieve the desired functionality. In various examples, the cap 603 may also be integrated into the sleeve as a single piece. Depending on the function desired, the sleeve 602 may be made of any vacuum-compatible material. The system of the insert 712, spring 707, and spring trap 706 may be reconfigured in many ways depending on the desired function. The spacers 604 may be in many different configurations and shapes. The ball joint brackets 710-711 may be reconfigured depending on the desired mobility of the ball joint. The embodiment provided exemplifies a general modular system configured for manipulating a tweezer 601, although this system can be reconfigured to accommodate a plurality of other tools.

In various implementations, optional aids such as spacers may be mounted on the tweezer tines to tune the squeeze force and ergonomic response when compressing the tines through the sleeve wall.

In an example, the portable sealed workstation may be modular in construction. The bracket geometry, ball size, sleeve length, compliance, spring rate, and tool coupling may be altered to suit different tasks. The manipulator module 600 may be installed in any convenient port location to optimize reach and visibility across the platform. Multiple modules may be used simultaneously. In alternative embodiments, the spring-bias system may be omitted or replaced with other force-balancing mechanisms; the sleeve can be rigid with an internal bellows; or a different articulation mechanism may be employed, provided that a hermetic seal is maintained and manual dexterity is preserved.

The portable sealed workstation may be designed to accommodate a hermetically sealable grid box 400, which may be utilized to store and transport EM specimen grids in a vacuum or gas environment. In an example, the grid box may comprise a base with a circular platform. The grid box may be constructed from stainless steel in one example. The grid box may be adapted with other materials to accommodate specific user applications. The base of the grid box may be designed to accommodate a plurality of grid slots distributed around the interior to receive standard EM grids.

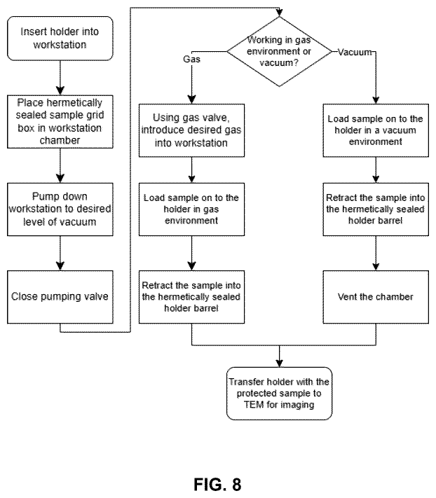

The portable sealed workstation may be configured to support multiple workflows involving the EM specimen. In an example, a workflow may be carried out using the workstation described therein in both loading in vacuum and in controlled gas. Referring to FIG. 8, the holder may be inserted into the workstation 801. The user may then place the hermetically sealed specimen grid box in the work station chamber and close the lid, operating the gridbox and EM grid using a manipulator module 600, thereby eliminating the need for the specimen to be exposed to detrimental environments and the need for specimens to be transported in multiple devices. The workstation may then be pumped down into vacuum.

In an example for operating the EM specimen in a vacuum setting, the portable sealed workstation may enable a user to place a gridbox into the gridbox slot 202 FIG. 2 and insert an EM holder into the workstation sleeve 122 FIG. 1. The user then may pump the chamber via the vacuum valve to a desired vacuum level. Once the workstation chamber is properly set to the desired vacuum setting, the user may open the grid box using the manipulator module tools inside the chamber. The EM specimen may now be manipulated by the user within the vacuum environment using the manipulator tools, while the user remains entirely outside the vacuum. Optionally, the user may, using the manipulator module, pick up a selected grid and load it onto the EM holder tip, securing the grid in place. The user may then retract the holder tip into the holder barrel, sealing the holder's internal volume if so desired. Finally, the user may vent the chamber via the valve and remove the holder for transfer to the EM.

In an example for operating the EM specimen in a controlled gas setting, the portable sealed workstation may enable a user to place a hermetic sealed grid box 300 into the gridbox slot 202 FIG. 2 and insert an EM holder into the workstation sleeve 122 FIG. 1. The user then evacuates and backfills the chamber via the gas valve to an appropriate pressure level with a selected gas. Once the workstation chamber 110 is properly set to the desired condition with the appropriate gas setting, the user may open the grid box using the manipulator module tools inside the chamber. The EM specimen may now be manipulated by the user within the controlled gas environment through the manipulator tools, while the user remains in a separate environment. Optionally, the user may, using the manipulator module, pick up a selected grid and load it onto the EM holder tip, securing the grid in place. The user may then retract the holder tip into the holder barrel, sealing the holder's internal volume if so desired. Finally, the user may vent the chamber via the valve and remove the holder for transfer to the electron microscope.

Gases used may be inert gases such as argon, or more exotic reactive gases such as ethane, provided the chamber and components that ensure a hermetically sealed environment are not made out of material that is compromised when exposed to said gas.

The user may operate the grid box transfer within the portable sealed gas station with a plurality of workflows. The specimen holder may allow the user to transport the EM grid, containing the EM specimen, into the workstation chamber. The user may then evacuate or backfill through a dedicated vacuum or gas valve before final tightening, or seal under ambient conditions as required. This allows the user to transport the sealed EM grid with reduced contamination risk.

The portable sealed workstation may be configured to comprise a variety of workstation geometries. The relative placement of the sleeve assembly, manipulator ports, and grid box dock/specimen holder may be reconfigured to suit different holder types and operator handedness. Multiple sleeves and manipulators may be provided to enable an impromptu configuration change. The lid 130 may be constructed as a single-piece lid or a multi-piece lid. Bearing and insert components may be omitted or integrated, wherein the sealing elements may be modified depending on the overall design changes.

One or more vacuum and gas valves may be placed on any housing face. Valves may be combined with gauges, regulators, or quick-connects. Additional ports may be added for purge/cycling, residual gas analysis, or leak-checking.

The portable sealed workstation may comprise a plurality of platform features. The platform apertures may vary in size and shape. The grid dock or specimen holder may be adapted to accept different grid box footprints. The grid dock or specimen holder may include anti-rotation pins, magnet seats, or clamps. The tip seat of the specimen holder may be tailored to different holder tips and clamps.

The portable sealed workstation may comprise a variety of manipulator modules. The specimen handling tool may comprise attachment means for interchanging tweezers, hooks, probes, or cutters. The sleeve for the manipulator modules may comprise a vacuum-compatible elastomer or polymer, or a metallic bellows with an elastomeric cuff. The specimen handling tool may comprise a spring with pre-load tension settings, which may be adjusted based on specific application needs. The ball-joint may be replaced by crossed-flexure pivots or gimbals. The bracket set may be adapted to any lid thickness and may incorporate quick-change couplings. O-ring sizes and gland designs may be altered while maintaining hermeticity.

The grid box design may be adapted to accommodate a plurality of applications. The sealing elements for the grid box may be O-rings or other hermetic seals. The lid may comprise a lid drive to facilitate handling, which may be hex, Torx, knurled, or tool-less. The lid may comprise lids that may be replaced by clamps or other latching mechanisms. The grid box may comprise anti-rotation means, which may be keyed flats, magnets, or friction features. Materials may be selected for weight, magnetic compatibility, corrosion resistance, or outgassing performance.

In various implementations, any manual step may be automated. For instance, grid transfer may be performed with a robotic end-effector through a sealed port, obviating one or more manipulator modules. In such cases, manipulator ports may be repurposed as automation interfaces.

Components in contact with vacuum or controlled gas preferably use low-outgassing materials and finishes. Metals (e.g., stainless steel, aluminum, titanium), glass, and vacuum-rated polymers (e.g., PEEK, PTFE, polyimides) may be employed. Seals can be made from fluorocarbon elastomers, silicone, perfluoro elastomers, or metal, depending on temperature, pressure, and/or chemical compatibility requirements. Surfaces may be bead-blasted, electropolished, anodized, or passivated as needed. Clear viewports may be glass, quartz, or vacuum-rated polymer. Fasteners and threads should be selected for repeatable sealing without galling; lubricants, if used, should be vacuum compatible.

If a gas is to be used inside the workstation, considerations must be made for the type of gas expected to be used and possible interactions between the gas and the materials with which the gas will be in contact.

The workstation may be positioned proximate to an electron microscope to reduce transfer times and environmental exposure. The hermetic integrity of the workstation sleeve assembly, manipulator module seals, and grid box may enable workflows without the use of glove boxes.

The workstation may accommodate different pressure regimes, including high-vacuum, rough-vacuum, and positive-pressure inert environments.

In some aspects, a workstation variant may omit manipulators where an automated pick-and-place module handles grids through a sealed port.

In some aspects, a single-seal grid box may use a single large O-ring with an offset groove to define the sealed volume.

In some aspects, a manipulator variant may utilize a rigid sleeve with an internal sliding shaft and external lever to actuate tweezer tines via a bell-crank, preserving a hermetic seal with dynamic shaft seals.

In some aspects, a lid variant may integrate multiple optical ports and lighting, with internal baffling to reduce glare and improve visual contrast during manipulation.

A camera may be installed to assist in viewing the inner chamber of the workstation. In some configurations, the viewing of the internal chamber may be entirely digital.

It should be understood that the foregoing embodiments can be combined or modified without departing from the spirit and scope of the invention. Features described with respect to one embodiment may be incorporated into others. All components identified as “necessary” in one configuration may be replaced by equivalents that provide substantially the same function.

The detailed description provided above in connection with the appended drawings is intended as a description of examples and is not intended to represent the only forms in which the present examples can be constructed or utilized.

It is to be understood that the configurations and/or approaches described herein are exemplary in nature, and that the described embodiments, implementations, and/or examples are not to be considered in a limiting sense, because numerous variations are possible.

The specific processes or methods described herein can represent one or more of any number of processing strategies. As such, various operations illustrated and/or described can be performed in the sequence illustrated and/or described, in other sequences, in parallel, or omitted. Likewise, the order of the above-described processes can be changed.

Although the subject matter has been described in language specific to structural features and/or methodological acts, it is to be understood that the subject matter defined in the appended claims is not necessarily limited to the specific features or acts described above. Rather, the specific features and acts described above are presented as example forms of implementing the claims.

What is claimed is:

1. A portable workstation for an electron microscopy (EM) specimen holder, comprising:
a hermetically sealable chamber housing defining an interior working volume,
a lid configured to hermetically seal the chamber housing, the lid including at least one manipulator port with a hermetic interface,
a manipulator module mounted on the manipulator port, wherein the manipulator module comprises a sleeve arranged to provide axial displacement and multi-axis articulation of the handling tool,
an EM holder receiver sleeve configured to receive an EM specimen holder such that a tip of the EM specimen holder is accessible within the interior working volume; and
at least one valve coupled to the chamber housing and configured to selectively evacuate the interior working volume and/or introduce a selected gas thereto.

2. The portable workstation of claim 1, wherein the chamber housing further comprises a lid track with a plurality of bearings configured to reduce the torque required for lid rotation under differential pressure.

3. The portable workstation of claim 1, wherein at least one valve comprises a vacuum valve and a gas valve configured to evacuate the interior working volume to a target vacuum level and/or to backfill the interior working volume with an inert gas to a target pressure.

4. The portable workstation of claim 1, further comprising an optical aid aligned to provide a field of view into the interior working volume, the optical aid including at least one viewport, lens, or camera mount.

5. The portable workstation of claim 1, wherein the hermetically sealed chamber comprises a receiver for a grid box.

6. The portable workstation of claim 1, wherein the grid box comprises a base including a plurality of grid slots, the base having an outer perimeter groove and an inner diameter groove configured to receive respective sealing elements,
a lid configured to mate with the base and compress the sealing elements to define a hermetically sealed interior volume encompassing the grid slots,
a central threaded interface between the lid and the base arranged to draw the lid against the sealing elements; and
an anti-rotation feature on the base configured to engage with a complementary feature on a dock to prevent rotation during lid manipulation.

7. The portable workstation of claim 1, wherein the manipulator module comprises a deformable sleeve to allow manipulation of the tool inside.

8. The portable workstation of claim 1, comprising a compression spring seated in the manipulator module.

9. A manipulator module for handling specimens in a controlled environment across a hermetically sealed interface, comprising:
at least one handling tool configured to transmit user-applied motions,
a sleeve arranged around at least one handling tool while maintaining a hermetic barrier between an exterior environment and an interior working volume,
a ball-joint articulation assembly coupled to the sleeve and configured to provide axial displacement and multi-axis articulation of the sleeve and the at least one handling tool,
a spring-bias system configured to preload the handling tool toward a neutral position, and
a hermetic interface adapted to mount the module to a lid of a workstation such that the handling tool accesses the interior working volume while a user actuates the handling tool from outside the chamber.

10. The manipulator module of claim 9, wherein at least one handling tool comprises tweezers, microprobes, grippers, or any handling tool used in the EM field.

11. The manipulator module of claim 9, wherein the ball-joint articulation assembly comprises a spherical joint received within a bracket set configured to clamp to the lid or wall of a chamber, the bracket set including O-ring gland seals disposed between the ball-joint and the brackets and between the brackets and the lid or wall to maintain a hermetic seal during articulation.

12. The manipulator module of claim 9, wherein the manipulator module includes spacers on tweezer tines to tune the squeeze force and ergonomic response when compressing the tines through the sleeve wall.

13. The manipulator module of claim 9, wherein the flexible sleeve comprises a vacuum-compatible elastomeric or polymeric tube configured to permit full range of motion while handling at least one handling tool.

14. The manipulator module of claim 9, wherein the sleeve comprises a metallic bellows segment with an elastomeric cuff to preserve hermeticity during tool actuation.

15. The manipulator module of claim 9, wherein the spring-bias system comprises a compression spring seated on a sleeve-mounted retainer that is configured to set a preload and provide consistent tactile feedback during tool actuation.

16. The manipulator module of claim 9, further comprising a tool configured to engage a grid box lid.

17. A method of handling an EM specimen in a controlled environment using a portable workstation, the method comprising:
inserting an EM specimen holder into a chamber housing until the tip of the EM specimen holder extends into an interior working volume,
placing a grid box containing at least one EM grid onto a grid box dock within the interior working volume,
sealing the chamber housing and operating at least one valve to establish a target environment within the chamber,
actuating, from outside the chamber housing, a manipulator module mounted to a manipulator port to operate a handling tool within the interior working volume,
opening the grid box within the interior working volume using the handling tool while the grid box base is held against rotation by an anti-rotation mechanism,
manipulating a selected EM grid with the manipulation module and loading the selected EM grid onto the EM specimen holder tip,
retracting the EM specimen holder tip into a holder barrel to seal the holder's internal volume and maintain a target environment within, when so configured, and
venting the chamber housing and removing the EM specimen holder for transfer to an electron microscope.

18. The method of handling an EM specimen in a controlled environment using a portable workstation of claim 17, further comprising establishing the target environment by pumping into vacuum.

19. The method of handling an EM specimen in a controlled environment using a portable workstation of claim 17, further comprising establishing the target environment by injecting a gas.

20. The method of handling an EM specimen in a controlled environment using a portable workstation of claim 17, comprising injecting the gas with an additional valve.
